(19) United States
(12) Patent Application Publication
(10) Pub. No.: US 2025/0298936 A1
(43) Pub. Date: Sep. 25, 2025

(54) System and Method for Acquiring and Utilizing Magnetic Flux Map Using Compressed Sensing

(71) Applicant: Mitsubishi Electric Research Laboratories, Inc., Cambridge, MA (US)

(72) Inventors: Dehong Liu, Cambridge, MA (US); Abhishek Patkar, Cambridge, MA (US); Yebin Wang, Cambridge, MA (US)

(73) Assignee: Mitsubishi Electric Research Laboratories, Inc., Cambridge, MA (US)

(21) Appl. No.: 18/614,906

(22) Filed: Mar. 25, 2024

(51) Int. Cl. G06F 30/20; H02P 23/14

(52) U.S. Cl. CPC G06F 30/20; H02P 23/14

(57) ABSTRACT

A magnetic flux mapping system for reconstructing a magnetic flux map efficiently from random measurements of a magnetic flux of an electric motor. The system first generates an intermediate reconstructed flux map dataset by performing a zero-padding method for the measurements of the magnetic flux, and then iteratively updates the flux map by FFT, soft-thresholding, inverse FFT, and data consistency steps until convergence. The flux map is used in motor control system to generate desired motor current, voltage, and speed to drive load.

### FIELD OF THE INVENTION

The present invention relates to the field of motor control, specifically acquiring the flux map of electric machines using a compressed sensing method with much fewer measurements than that required by conventional flux map acquisition methods and formulating an analytical model to efficiently compute the magnetic flux given stator current and rotor angle instead of using a look-up table in the control loop.

### BACKGROUND OF THE INVENTION

Electric machines are being increasingly used across various industries such as electric vehicles, home appliances, power generation, etc. A variety of synchronous machines such as Interior Permanent Magnet machine (IPM), surface mount permanent magnet synchronous machine (PMSM) and Synchronous reluctance machine (SynRM), etc., have been deployed depending on the application requirement. With the advent of data driven control and an increasing demand for precise motor operation, more and more sophisticated control strategies such as Maximum Torque per Ampere (MTPA), Maximum Torque per Volts (MTPV), and Model Predictive Control (MPC) have been proposed. Such advanced control strategies require an accurate magnetic model to achieve the specified control performance.

The magnetic model characterizes the magnetic flux as a function of the stator current in a reference frame of choice for 2D flux map. To capture spatial harmonics of the flux, a 3D flux map is considered, which is also a function of the rotor angle position. For instance, in the d-q reference frame, the magnetic model characterizes the magnetic flux maps in q- and d-axis, ϕ_{q} and ϕ_{d}, as a function of the stator current in d- and q-axis (I_{d}, I_{q}) for 2D flux map, i.e., ϕ_{d}=f_{2d}(I_{d}, I_{q}) and ϕ_{q}=f_{2q}(I_{d}, I_{q}), respectively, and as a function of the stator current (I_{d}, I_{q}) and the rotor angle position θ for 3D flux map to capture spatial harmonics, i.e., ϕ_{d}=f_{3d}(I_{d}, I_{q}, θ) and ϕ_{q}=f_{3q}(I_{d}, I_{q}, θ). However, the magnetic model for IPMs and SynRMs is highly nonlinear owing to saturation and cross-saturation effects. Moreover, spatial harmonics need to be considered while inferring a magnetic model as they lead to torque ripples.

To identify the magnetic model, it is crucial to conduct experiments to acquire the magnetic flux under different stator currents. Although a viable approach to identifying the magnetic model is Finite Element Analysis (FEA), FEA-based identification is typically not readily available to end users. Moreover, the FEA-based model needs to be validated through experiments to guarantee its accuracy.

However, there are two major issues for magnetic flux map identification by experiments. First, it is very time-consuming to collect enough data for an accurate magnetic model. Experimental identification often requires conducting tests at sufficiently dense grid-points of current (I_{d}, I_{q}) to accurately capture flux variation. Such a grid should span the operating range of the motor under test. In the case of motors containing permanent magnets, additional care must be taken to avoid demagnetization due to the overheating issue in experiments. To save testing time and to reduce risks of demagnetization in case of PM motors, it is thus desirable to reduce the number of tests conducted without compromising the accuracy of the acquired flux map. Second, the application of the magnetic model is also critical for high performance control. Identified magnetic models are typically stored in a 2D or 3D look-up table. However, there is a trade-off between the access speed and the flux accuracy since every current-flux point of interest needs to be searched in the look-up table to find some nearest points and then interpolated using these nearest points to achieve an accurate point value. Moreover, derivatives of the flux map, which is necessary for computing control inputs, need to be approximated, impacting the performance of the control algorithms.

To address these issues, significant research efforts have been dedicated towards developing analytical magnetic models accounting for the nonlinear effects. For instance, Ortombina et al. proposed using Radial Basis Functions (RBFs) to get a black box model for the flux maps. Bedetti et al. put forth a novel saturation function approach to identify the magnetic model at stand-still using just three constants. However, to capture the cross-saturation behavior, these constants that characterize self saturation behavior need to be adjusted at different test points. Qu et al. proposed a polynomial model to capture the nonlinear effect, treating the d-q axis currents as a state variable and the flux as independent variables. Hinkkanen et al. utilized the aforementioned polynomial model for self-commissioning application. All the aforementioned approaches consider saturation and cross-saturation but not spatial harmonics. Modeling spatial harmonics is necessary to mitigate torque ripples. Kano et al. proposed modeling the flux map using a Fourier series in the electrical angle θ and a polynomial basis in d-q axis currents. However, to perform numerical fitting, significant data points in (I_{d}, I_{q}, θ) dimensions are required. Boesing et al. also utilize Fourier series to model the θ dependence but utilize look-up tables to store Fourier coefficients to capture d, q flux variation.

Therefore, there is a need to develop a system and method to efficiently acquire the accurate magnetic flux map of electric machines and to utilize the map in high precision control.

### SUMMARY OF THE INVENTION

It is an object of some embodiments of an invention to provide a system and a method suitable for getting an analytical expression for 2D and 3D flux maps from limited data samples, wherein 2D flux maps refer to the forward maps that model the flux as a function of d-axis current and q-axis current (I_{d}, I_{q}) and neglect any influence of spatial harmonics related to the rotor electrical angle θ, whereas 3D flux maps refer to forward maps that model the flux as a function of (I_{d}, I_{q}, θ). Compressed sensing aims to recover a sparse representation in an appropriate basis such as Fourier, using limited samples of the original signal. Under certain conditions on the signal and the acquired samples, the original signal can be recovered with high probability using fewer samples than mandated by the Nyquist criterion.

Some embodiments of the present invention can provide a compressed sensing based approach to getting an analytical expression for 2D and 3D flux maps from limited data samples. According to some embodiments of the present invention, 2D flux maps refer to the forward maps that model the flux as a function of d-axis current and q-axis current (I_{d}, I_{q}) and neglect any influence of spatial harmonics related to the rotor electrical angle θ, whereas 3D flux maps refer to forward maps that model the flux as a function of (I_{d}, I_{q}, θ). Compressed sensing aims to recover a sparse representation in an appropriate basis such as Fourier or wavelet basis, using limited samples of the original signal. Under certain conditions on the signal and the acquired samples, the original signal can be recovered with high probability using fewer samples than mandated by the Nyquist sampling rate.

The objectives include to use much fewer randomly sampled data-points than that required by Shannon-Nyquist sampling rate to build a high-fidelity 2D and 3D flux map model, to provide an analytical 3D magnetic model accounting for spatial harmonics, and to avoid time-consuming process of searching a look-up table and interpolating nearby data points.

Some embodiments of the invention use much fewer randomly sampled data-points than that required by conventional methods to build a high-fidelity 2D and 3D flux map model.

Some embodiments of an invention provide an analytical 3D magnetic model accounting for spatial harmonics to avoid time-consuming process of searching a look-up table and interpolating nearby data points.

According to some embodiments of the present investigation, a system and method of acquiring an analytical magnetic model is provided, which enables to perform fewer measurements for electric machines. The method includes steps measuring magnetic flux data (magnetic flux measurement dataset) from limited randomly sampled data points in the operating current range, applying compressed sensing method to reconstruct the whole 2D and 3D flux map in the operating current range, formulating an analytical magnetic model to efficiently compute the magnetic flux at any given stator current and rotor angle, feeding in the magnetic model in the motor control loop for high performance control.

Some embodiments of the present invention provide a magnetic flux mapping system for reconstructing a magnetic flux map from measurements of a magnetic flux of an electric motor. The system may include an interface circuit connected to a database storage and configured to receive the measurements of the magnetic flux of the electric motor (magnetic flux measurement dataset) from a data storage via a network; one or more processors; a memory having stored thereon a set of instructions for reconstructing the magnetic flux map, which when performed by the one or more processors, cause the one or more processors to at least performs steps of: generating an intermediate reconstructed flux map dataset by performing a zero-generating a discrete Fourier Transform (DFT) dataset by performing a Fast Fourier Transformation (FFT) for the intermediate reconstructed flux map dataset; generating a soft-thresholded dataset by performing a soft-thresholding process for the DFT dataset based on a regularizing threshold; reconstructing a new intermediate magnetic flux map from an inverse-FFT dataset by performing an inverse-FFT process for the soft-thresholded dataset; performing a data-consistency enforcement process for the reconstructed magnetic flux map to update the reconstructed new magnetic flux map by using measured flux map points to replace with the corresponding reconstructed flux map points, until a convergence condition defined by a convergence parameter is met; storing the newly reconstructed magnetic flux map into a memory, wherein each entry of the updated reconstructed magnetic flux map is represented by q-axis fluxes and d-axis fluxes, as a function of q-axis current I_{q}, d-axis current I_{d}, and rotor electrical angle position θ, respectively.

Further, another embodiment of the present invention provide a non-transitory computer-readable medium having stored thereon a set of instructions for reconstructing a magnetic flux map from measurements of a magnetic flux of an electric motor, which when performed by one or more processors, cause the one or more processors to at least performs steps of: generating an intermediate reconstructed flux map dataset by performing a zero-padding method for the measurements of the magnetic flux; and iteratively generating a discrete Fourier Transform (DFT) dataset by performing a Fast Fourier Transformation (FFT) for the intermediate reconstructed flux map dataset; generating a soft-thresholded dataset by performing a soft-thresholding process for the DFT dataset based on a regularizing threshold; reconstructing a new intermediate magnetic flux map from an inverse-FFT dataset by performing an inverse-FFT process for the soft-thresholded dataset; performing a data-consistency enforcement process for the reconstructed magnetic flux map to update the reconstructed new magnetic flux map by using measured flux map points to replace with the corresponding reconstructed flux map points, until a convergence condition defined by a convergence parameter is met; storing the newly reconstructed magnetic flux map into a memory, wherein each entry of the updated reconstructed magnetic flux map is represented by q-axis fluxes and d-axis fluxes, as a function of q-axis current I_{q}, d-axis current I_{d}, and rotor electrical angle position θ, respectively.

### BRIEF DESCRIPTION OF THE DRAWING

The presently disclosed embodiments will be further explained with reference to the attached drawings. The drawings shown are not necessarily to scale, with emphasis instead generally being placed upon illustrating the principles of the presently disclosed embodiments.

While the following identified drawings set forth presently disclosed embodiments, other embodiments are also contemplated, as noted in the discussion. This disclosure presents illustrative embodiments by way of representation and not limitation. Numerous other modifications and embodiments can be devised by those skilled in the art which fall within the scope and spirit of the principles of the presently disclosed embodiments.

FIG. 1A shows a schematic diagram of a motor drive system including a magnetic flux mapping function;

FIG. 1B is a diagram indicating q-axis and d-axis of a motor, where the d-axis is direct magnetic axis and always lying in the direction of the magnetic field of the rotor permanent magnets, and the q-axis is quadrature magnetic axis turned by 90 electrical degrees (not necessary 90 spatial degrees);

FIG. 1C is a flow chart for reconstructing the flux-map from the measurements of the magnetic flux from sensors or measurement database;

FIG. 2 and FIG. 3 illustrate the Fourier coefficients of q, d axis flux maps, arranged in decreasing order of magnitude, respectively;

FIG. 4 shows an exemplar plot of a 2D flux map of ϕ_{q} acquired by high-fidelity simulation;

FIG. 5 shows an exemplar plot of a 2D compressed flux map of \hat{ϕ}_{q} with 10% of the most dominant Fourier coefficients;

FIG. 6 shows an exemplar plot of a 2D flux map of ϕ_{d} acquired by high-fidelity simulation;

FIG. 7 shows an exemplar plot of a 2D compressed flux map of \hat{ϕ}_{d} with 10% of the most dominant Fourier coefficients;

FIG. 8 illustrate a soft-thresholding based iterative algorithm used to solve the optimization problem of reconstructing the flux map;

FIGS. 9 and 10 depict exemplar plots of random samples, across the (I_{d}, I_{q}) grid from true flux maps ϕ_{q} and ϕ_{d}, wherein the random samples are used to reconstruct the q and d axis flux maps \hat{ϕ}_{q} and \hat{ϕ}_{d}, respectively;

FIGS. 11 and 12 show the corresponding reconstructed flux maps \hat{ϕ}_{q} and \hat{ϕ}_{d} using the random samples in FIG. 9 and FIG. 10, respectively;

FIGS. 13 and 14 show the reconstruction error between the true flux maps (FIG. 4 and FIG. 6) and reconstructed flux maps (FIG. 11 and FIG. 12) in the q and d axis, respectively;

FIG. 15 shows the variation of the root mean squared error (RMSE) between the true and reconstructed flux maps as function of the percentage of data-points used for reconstruction;

FIG. 16 shows another exemplar plot of random samples, across the (I_{d}, I_{q}) grid from true 2D flux maps ϕ_{q} shown in FIG. 17, wherein the random samples are used to reconstruct the q axis flux maps \hat{ϕ}_{q};

FIG. 17 shows another exemplar plot of 2D flux map of ϕ_{q} acquired by high-fidelity simulation;

FIG. 18 shows the corresponding reconstructed 2D flux maps \hat{ϕ}_{q} using the random samples in FIG. 16;

FIG. 19 shows the reconstruction error between the true 2D flux map (FIG. 17) and reconstructed 2D flux map (FIG. 18) in the q axis;

FIG. 20 compares the true flux variation, the random samples used, and the reconstructed flux map variation in a slice of an exemplar 3D flux map in the q axis with respect to θ at a fixed (I_{d}, I_{q}) grid point; and

FIG. 21 compares the true flux variation, the random samples used, and the reconstructed flux map variation in a slice of an exemplar 3D flux map in the d axis with respect to θ at a fixed (I_{d}, I_{q}) grid point.

### DETAILED DESCRIPTION OF THE PREFERRED EMBODIMENTS

The following description provides exemplary embodiments only, and is not intended to limit the scope, applicability, or configuration of the disclosure. Rather, the following description of the exemplary embodiments will provide those skilled in the art with an enabling description for implementing one or more exemplary embodiments. Contemplated are various changes that may be made in the function and arrangement of elements without departing from the spirit and scope of the subject matter disclosed as set forth in the appended claims.

Specific details are given in the following description to provide a thorough understanding of the embodiments. However, understood by one of ordinary skill in the art can be that the embodiments may be practiced without these specific details. For example, systems, processes, and other elements in the subject matter disclosed may be shown as components in block diagram form in order not to obscure the embodiments in unnecessary detail. In other instances, well-known processes, structures, and techniques may be shown without unnecessary detail to avoid obscuring the embodiments. Further, like reference numbers and designations in the various drawings indicated like elements.

According to an embodiment of the present invention, a magnetic flux mapping system is for reconstructing a magnetic flux map of an electric motor from measurements (samples) of a magnetic flux map of the electric motor. The magnetic flux mapping system is configured to include at least a processor and a memory storing instructions which cause the processor to at least performs steps of: generating a zero-padded flux map dataset by performing a zero-padding method for the measurements of the magnetic flux; generating a discrete Fourier Transform (DFT) dataset by performing a Fast Fourier Transformation (FFT) for the zero-padded flux map dataset; generating a Soft-threshold dataset by performing a Soft-threshold process for the DFT dataset based on a regularizing threshold; reconstructing the magnetic flux map from an inverse-FFT dataset by performing an inverse-FFT process for the soft-thresholded dataset;
performing a data-consistency enforcement process for the reconstructed magnetic flux map to update the reconstructed magnetic flux map by using measurements to replace the corresponding reconstructed flux map points and keeping reconstructed flux map points for those unmeasured points, wherein the steps of the generating the DFT through the performing the data-consistency enforcement process are iteratively continued until a convergence condition defined by a convergence parameter; and storing the updated reconstructed magnetic flux map into a memory, wherein each entry of the updated reconstructed magnetic flux map is represented by q-axis flux ϕ_{q} as a function of d-axis currents I_{d}, and q-axis currents I_{q} for 2D flux map, i.e. ϕ_{q}=f_{2q}(I_{d}, I_{q}), or as a function of d-axis currents I_{d}, q-axis currents I_{q}, and electrical angle θ, i.e., ϕ_{q}=f_{3q}(I_{d}, I_{q}, θ) for 3D flux map, and d-axis flux ϕ_{d} as a function of d-axis currents I_{d}, and q-axis currents I_{q} for 2D flux map, i.e. ϕ_{d}=f_{2d}(I_{d}, I_{q}), or as a function of d-axis currents I_{d}, and q-axis currents I_{q}, and electrical angle θ, ϕ_{d}=f_{3d}(I_{d}, I_{q}, θ) for 3D flux map.

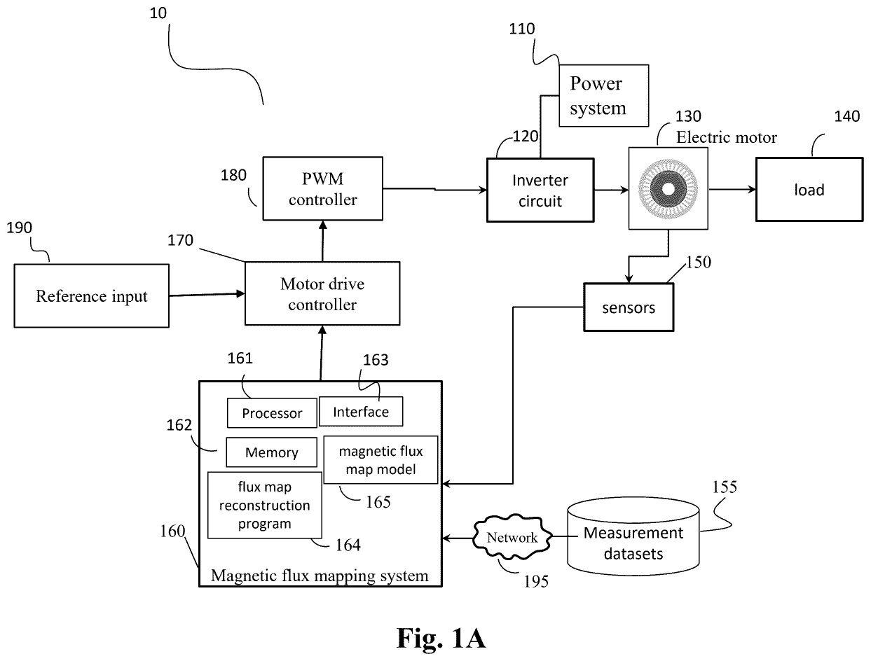

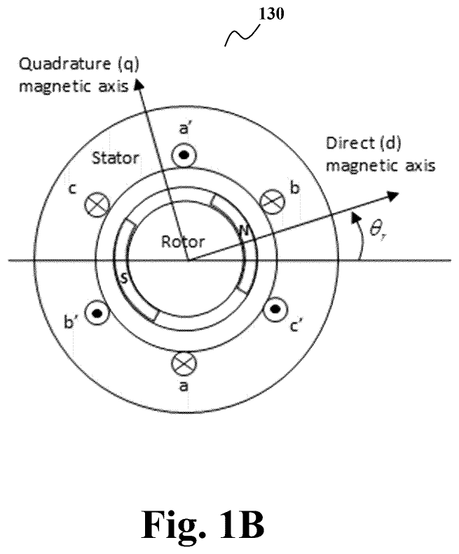

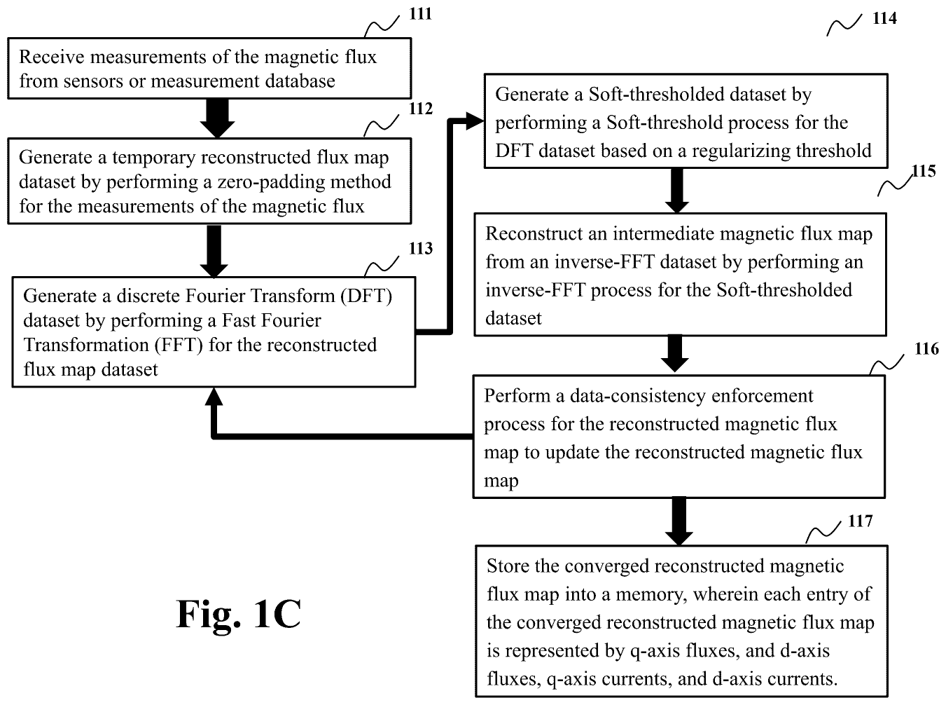

FIG. 1 is a schematic diagram illustrating a non-limiting example of an inverter-fed motor-drive system 10 including a magnetic flux mapping system 160 according to one embodiment of an invention. Generally, the motor-drive system 10 includes the power system 110, an inverter 120, an electric motor 130, and a load 140.

Accordingly, the inverter 120 may be used for controlling the operation of the electric motor 130 to meet the requirement of the load 140 in response to various inputs such as speed, torque, position, in accordance with embodiments of the present invention. For example, the inverter 120 coupled with the electric motor 130 can control the speed of the load 140, such as an electric vehicle, based on inputs received from sensors 150 configured to acquire data (operation signals) pertaining to operating conditions of the electric motor 130. As another example, the inverter 120 coupled with the electric motor 130 can control the position of the load 140, such as a robot arm, based on inputs received from sensors 150 configured to acquire data pertaining to operating conditions of the electric motor 130. As another example, the inverter 120 coupled with the electric motor 130 can control the torque of the load 140, such as a traction machine, based on inputs received from sensors 150 configured to acquire data pertaining to operating conditions of the electric motor 130.

According to certain embodiments, the sensors 150 may be electrical signal sensors such as current and/or voltage sensors for acquiring current and/or voltage data pertaining to the induction motor 100. For example, a current sensor may sense current data from one or more of the multiple phases of the electric motor. More specifically, in the case of the electric motor embodied as a 3-phase electric motor, current sensors and voltage sensors sense current data and voltage data from the each of the three phases of the 3-phase electric motor. While certain embodiments of the present invention will be described with respect to a multi-phase electric motors, other embodiments of the present invention can be applied to other multi-phase electromechanical machines. According to another embodiment, the sensors 150 may be position sensors such as the position angle of the rotor of the electric motor 150.

According to certain embodiments, the load 140 driven by the electric motor 130 could be a factory machine, a robot arm, a traction machine, or even aspects of transportation system such as an electric vehicle, a train, etc.

The magnetic flux mapping system 160 includes a processor 161, a memory 162, a signal interface (interface circuit or data interface) 163, a magnetic flux map reconstruction program 164, and a magnetic flux map model 165. Sensor data 155 and the magnetic model program 164 stored in a storage to be uploaded to the memory 162 when the instructions of the programs 164 are performed by the processor 161. The interface circuit 163 is connected to a data server (data storage) 155 and configured to receive the measurements of the magnetic flux of the electric motor 130 from the data server 155 via a network 195. The network 195 can be a wired or a wireless communication network. The data server 155 is configured to store datasets for the measurements of the magnetic flux of the electric motor, in which the magnetic flux measurements are performed independently from the magnetic flux mapping system 160. For instance the measurements of the magnetic flux may be torque measurement datasets of the electric motor.

During operation, the real-time sensor data, including current, voltage, and position data are collected as input of the magnetic flux mapping system 160. The magnetic flux mapping system 160 then generates corresponding flux value according to the magnetic flux map model. The flux value will be used in the motor drive controller 170 to calculate the real-time torque and/or speed of the electric motor 130. Compared to the reference value 190 (such as required speed and/or torque) required by the load, motor drive controller 170 calculates the control signal and send it to the PWM controller 180 such that the switches of the inverter circuit 120 can be controlled by the PWM controller 180 to generate the proper voltage/current signal (setting signal) for the electric motor 130. In other words, the setting signal is provided from the PWM controller or motor controller.

FIG. 1B is a diagram illustrating q-axis and d-axis of an electric motor 130. The figure shows a basic diagram of an electric motor highlighting the rotor, stator, and the d and q axes.

The d-axis is a reference axis that lies along the direction of the rotor's magnetic field. In the context of synchronous machines, it is aligned with the rotor's permanent magnets or the field winding in the case of wound rotor machines.

The -axis is orthogonal (at a right angle) to the d-axis and does not align with the rotor's magnetic field.

In the motor control system, such as those used in electric vehicles or industrial automation, the precise manipulation of I_{d} and I_{q} allows for the independent control of torque and magnetic flux. By adjusting these currents, Id and Iq, in a synchronous frame of reference (rotating with the rotor), it is possible to achieve accurate high-performance control over the motor

### Magnetic Flux Maps

A magnetic flux map would typically show lines of magnetic flux density, with different contrast or line densities representing different levels of flux. In the context of the electric motor, this map is used to display how the magnetic field is distributed across the air gap between the rotor and the stator, as well as within the core materials.

d-Axis Flux

The d-axis flux is the total magnetic flux generated by the stator current and the permanent magnet in the d-axis direction.

q-Axis Flux

The q-axis flux is the total magnetic flux generated by the stator current and the permanent magnet in the q-axis direction.

### Control Using Flux Maps

To accurately control the motor, one can use various control strategies such as Field oriented control (FOC), Maximum Torque per Ampere (MTPA), Maximum Torque per Volts (MTPV), and Model Predictive Control (MPC), etc., to control the motor speed, torque, and position, etc.

According to an embodiment of the present invention, the control system may use sensorless algorithms that estimate the rotor position and speed from the motor's voltage and current measurements. These algorithms rely on understanding the magnetic flux maps to infer the motor's operating point without the need for physical sensors.

By analyzing the magnetic flux maps at different operating points, we can identify areas of magnetic saturation or excessive leakage flux, which can be optimized to improve motor efficiency. Adjustments to the motor design, such as the geometry of the stator and rotor or the material properties, can be made based on the insights from these maps.

For instance, the following steps can be included to perform the accurate control of a motor. Initialization: Set the reference frame for control, aligning the d-axis with the rotor's magnetic field; Flux Mapping: Use sensors or estimations to determine the actual flux distribution in the motor under various load conditions; Control Algorithm: Implement a PID controller or more advanced algorithms to adjust the d-axis and q-axis currents based on the desired torque and flux; Feedback Loop: Continuously monitor the motor's back EMF, current, and voltage to update the control inputs and maintain optimal performance. By applying these technical steps, the control system can finely tune the motor's response to provide precise control over its speed and torque, ensuring efficient operation across a wide range of conditions.

FIG. 1C is a flow chart for reconstructing the flux-map from the measurements of the magnetic flux from sensors or measurement database. First measurements of the magnetic flux from sensors or previous measurements database 111 are used as input of the program. For efficiency, only a fraction of the flux map data points are measured. Based on these measurements, a temporary reconstructed flux map is generated by performing a zero-padding method of the measurements of the magnetic flux 112, i.e., setting unmeasured flux map points to zeros. A discrete Fourier transform (DFT) is then performed on the reconstructed flux map dataset using a Fast Fourier transform (FFT) method 113 to generate a discrete DFT dataset. The DFT dataset is then denoised by a soft-thresholding process 114 to generate a soft-thresholded dataset, which is a sparse signal according to the assumption of compressed sensing technology. An intermediate magnetic flux map is then generated by performing an inverse-FFT process on the soft-thresholded dataset 115, wherein the intermediate flux map values changed from the original zero-padded flux map due to the soft-thresholding process. A data-consistency enforcement process 116 is performed on the intermediate magnetic flux map using the following steps. For those points on the flux map whose flux values are measured will be replaced by the measured flux values, and for those points on the flux map whose flux values are unmeasured will remain as the reconstructed intermediate flux map values. If the relative error between the newly reconstructed flux map values and the previously reconstructed flux map values is smaller than a certain preset value, meaning the program converged, the newly reconstructed flux map values are stored as the converged reconstructed magnetic flux map into memory 117, wherein each entry of the converged reconstructed magnetic flux map is represented by q-axis fluxes/d-axis fluxes as a function of q-axis currents, d-axis currents, and rotor electric angle. The newly reconstructed flux map values will be used to calculate flux given real-time measurements of the motor current and rotor angular position in the control loop.

### Magnetic Flux Map Acquisition Via Compressed Sensing

In the present disclosure, a magnetic flux map is referred to as a flux map. A variety of signals, particularly in the audio and image domain are observed to be compressible. This implies that such signals can be accurately represented by a few active modes in an appropriate basis, such as Fourier basis, wavelet basis, or other learned dictionaries. Compressed sensing aims to recover this sparse representation in an appropriate basis using limited samples of the original signal. In fact, in recovering sparse signals, it may be possible to relax the Shannon-Nyquist sampling theorem and the sparse signal may be recovered with high probability using fewer measurements than dictated by the Nyquist rate. Compressing techniques and compressed sensing have been extensively applied for image and audio processing.

Let x∈ [symbol] be a compressible signal. There exists a basis Ψ such that

$$x = Ψ s , \qquad ( 1 )$$

where s∈ [symbol] is a sparse vector. If s has at most K non-zero elements, x is K-sparse. The measurements y∈ [symbol] with (K<p<<n) is given by

$$y = C x , \qquad ( 2 )$$

where C∈ [symbol] is the measurement matrix. Compressed sensing seeks to find a sparse vector ŝ such that

$$\hat{s} = arg {min}_{s} {‖ s ‖}_{0} subject to y = C Ψ s , \qquad ( 3 )$$

where ∥⋅∥₀ is the l₀ norm referring to the cardinality of s. The non-convex optimization in (3) may be relaxed to a l₁-minimization problem as

$$\hat{s} = arg {min}_{s} \begin{matrix}{‖ s ‖}_{1} & \text{subject to} y = C Ψ s ,\end{matrix} \qquad ( 4 )$$

where ∥⋅∥₁ is the l₁ norm given by ∥s∥₁=Σₖ₌₁ⁿ|sₖ| if C is incoherent with respect to Ψ
Number of measurements p are sufficiently large

$$p \approx 𝒪 ( K log ( \frac{n}{K} ) ) .$$

To satisfy the incoherence property, we use random samples of the flux map. We also study the variation of reconstruction error with the number of measurements. An alternative formulation of (4) is given by

$$\hat{s} = arg {min}_{s} \frac{1}{2} {‖ y - C Ψ s ‖}_{2} + λ {‖ s ‖}_{1} , \qquad ( 5 )$$

where Δ≥0 is a regularizer weighing the importance of a sparse solution. In this paper, the formulation presented in (5) is used.

### Compressibility of Flux Maps

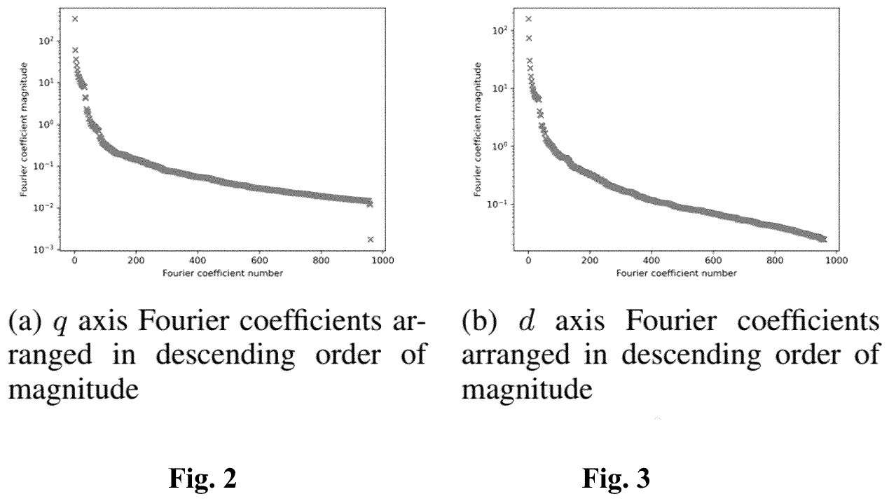

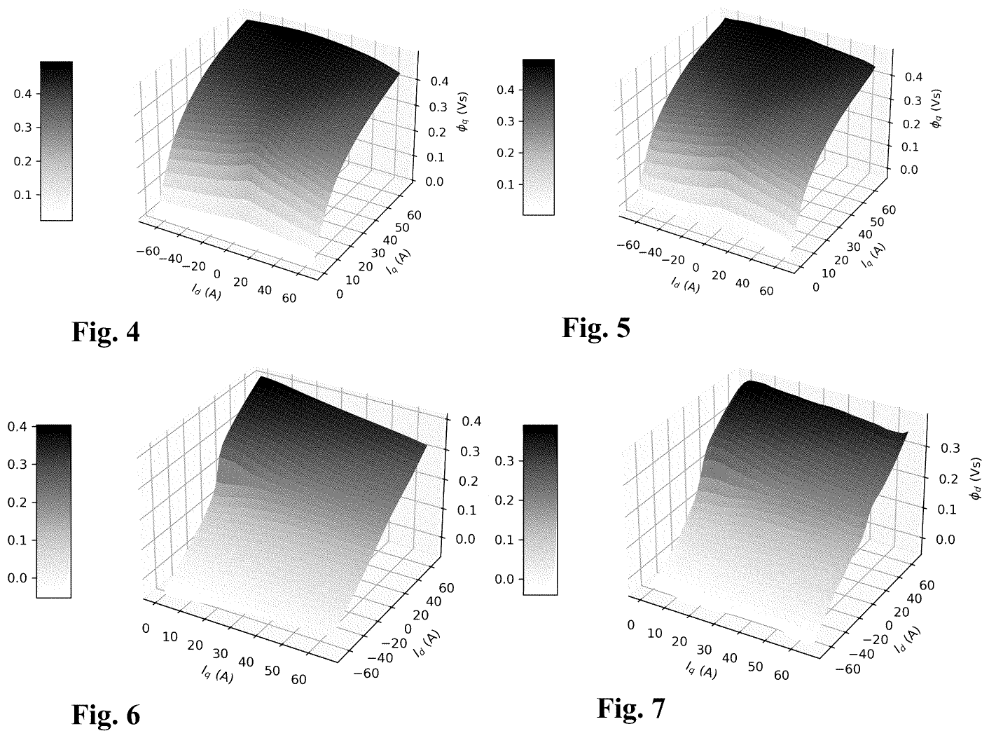

In this subsection, we empirically demonstrate that q and d axis flux maps are compressible in the Fourier domain. To that end, we use readily available FEM data sets through SyR-e (Synchronous Reluctance-evolution). Let ϕ_{q}(I_{d}, I_{q}) and ϕ_{d}(I_{d}, I_{q}) denote the q and d axis flux maps respectively. Let Φ_{q} and Φ_{d} denote the corresponding 2D Fourier spectra. For the THOR (name of a PM-SyR machine for light traction) data set chosen, we have a 31×31 data grid in (I_{d}, I_{q}) plane. Thus the Discrete Fourier Transform (DFT) of this data set will have 31×31 entries. The DFT was calculated using the Fast Fourier Transform (FFT) algorithm. FIGS. 2 and 3 illustrate the Fourier coefficients arranged in decreasing order of magnitude for q, d axis flux maps respectively. From FIGS. 2 and 3, it can be seen that the magnitude of Fourier components exponentially decreases in magnitude. FIGS. 4 and 5 compare the true and compressed maps of ϕ_{q}. FIGS. 6 and 7 compare the true and compressed maps of ϕ_{d}. In both cases, the compressed maps are acquired by retaining 10% of the most dominant DFT components. The Root Mean Squared Error (RMSE) in reconstructing the flux maps with dominant 10% DFT components was found to be 0.003 and 0.006 for the q and d axis respectively. From FIGS. 4, 5, 6, and 7 and the low RMSE, it can be concluded that the flux maps in both d and q axes are compressible in the Fourier domain. Since all motor flux maps exhibit similar behavior, it can be empirically concluded that the 2D flux maps are compressible in Fourier domain. The number of non-zero elements of the DFT depends upon the original DFT grid and the function variation with I_{d}, I_{q}. A similar argument can be made to conclude that the 3D flux map is also compressible albeit requiring a higher number of non-zero DFT entries.

### Mathematical Preliminaries

In this subsection, we elaborate on the relation between the flux maps and the formulation presented in (1)-(5) for the 3D case. Let ϕ be the true unknown discrete flux map with dimensions N₁, N₂, and N₃ respectively. Let Φ be the corresponding Fourier transform. Partial measurements of the flux map are denoted by ϕₚ. We use ϕ_{zp} to denote the map after zero-padding ϕₚ at unmeasured values and use the subscript u to denote a matrix unrolled in column major-order into a 1-D vector. Let ϕᵤ=Ψs with Fourier basis Ψ and sparse vector of Fourier coefficients s. Then the flux map reconstruction problem can be formulated along (1)-(5) as

$$\hat{s} = arg {min}_{s} \frac{1}{2} {‖ {( {ϕ}_{p} )}_{u} - C Ψ s ‖}_{2} + λ {‖ s ‖}_{1} , \qquad ( 6 )$$

where the entries of the measurement matrix C can be readily seen as

$$C ( a , b ) = \{ \begin{matrix}1 & if {( {ϕ}_{p} )}_{u} [ a ] = {ϕ}_{u} [ b ] \\ 0 & otherwise\end{matrix} .$$

Once the sparse Fourier coefficients are achieved by solving (6), the flux map can be reconstructed as

$${\hat{ϕ}}_{u} = Ψ \hat{s} . \qquad ( 7 )$$

To help in the construction of the Fourier basis matrix Ψ, we first define the N×N DFT matrix W for an N-sample 1D signal as:

W_{N}[c,d]=W_{N}^{cd},

where

$${W}_{N} = {e}^{- \frac{j 2 π}{N}} .$$

The corresponding inverse DFT matrix is given by

$${W}_{N}^{- 1} [ g , h ] = \frac{1}{N} {\overline{W}}_{N}^{g h} ,$$

where

$${\overline{W}}_{N} = {e}^{\frac{j 2 π}{N}} .$$

Now, the relationship between Φᵤ and ϕᵤ can then be given as

$${Φ}_{u} = ( {W}_{{N}_{3}} ⊗ {W}_{{N}_{2}} ⊗ {W}_{{N}_{1}} ) {ϕ}_{u} , \qquad ( 8 )$$

where W_{N}_{₃}⊗W_{N}_{₂} is the kronecker product between two matrices. Now the Fourier basis matrix Ψ can be inferred as the inverse of the forward transformation in (8). Thus for the 3D case, we have

$$Ψ = {W}_{{N}_{3}}^{- 1} ⊗ {W}_{{N}_{2}}^{- 1} ⊗ {W}_{{N}_{1}}^{- 1} \qquad ( 9 )$$

The Ψ matrix for the 2D case can be computed in a similar fashion. It can be readily seen that Ψ⁻¹=(W_{N}_{₃}⊗W_{N}_{₂}⊗W_{N}_{₁}). While (9) defines the Fourier basis matrix for mathematical completeness, in practice, the algorithm 1 uses FFT and inverse-FFT for efficient implementation.

### Magnetic Flux Map Reconstruction Algorithm

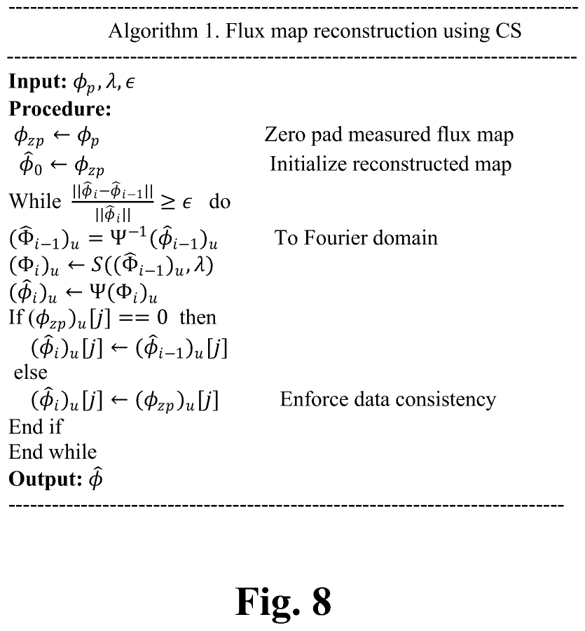

In this subsection, the algorithm used to reconstruct the magnetic flux map from limited random samples is explained. To solve the optimization problem given in (6), a soft-thresholding based iterative algorithm is used, as illustrated in FIG. 8. First, partial measurements of the flux map ϕₚ are zero-padded at unknown values to get the zero-padded flux map ϕ_{zp}. The reconstructed flux map \hat{ϕ} is then initialized as ϕ_{zp}. Next, the flux-map is transformed into the sparse Fourier domain using FFT. A soft-thresholding function S(u,λ) is then applied in the Fourier domain, where the soft-thresholding function is defined as

$$S ( u , λ ) = \{ \begin{matrix}0 & if \vert u \vert \leq λ \\ \frac{\vert u \vert - λ}{\vert u \vert} u & if \vert u \vert > λ\end{matrix} . \qquad ( 10 )$$

Here |⋅| computes the absolute value and the threshold λ is the regularizing parameter used in (6). The threshold λ is empirically tuned. To begin with, the threshold may be set to 5% of the maximum DFT coefficient of ϕ_{zp}.

After applying inverse-FFT, data-consistency is enforced to make sure the entries that are measured are consistent across ϕₚ and \hat{ϕ}. The iterative algorithm runs until convergence, which is determined by ϵ, a parameter chosen a priori.

### Example of Experimental Results

The proposed compressed sensing based approach is applied to reconstruct 2D and 3D flux maps using FEM data.

### 2D Flux Map Reconstruction

The THOR and syreDefaultmotor datasets, available in Syre in the PM orientation, are used as simulation data. The flux map data for the THOR motor is available as a function of {I_{d}, I_{q}, θ} in a 31×31×180 grid respectively. The 2D flux map is calculated by averaging along θ axis, given ϕ_{q}(I_{d}, I_{q}) and ϕ_{d}(I_{d}, I_{q}) respectively. Thus this flux map consists of 961 data-points on a grid for I_{d} from −66.11 A to 66.11 A and I_{q} from 0 A to 66.11 A. First, 40% of data-points are randomly sampled from the available flux map to get ϕ_{qp}(I_{q}, I_{d}), ϕ_{dp}(I_{q}, I_{d}). In experimental flux map identification, this operation would correspond to acquiring flux data at random I_{d}, I_{q} grid-points. The algorithm proposed in section 2 is then applied to reconstruct the flux map at the missing grid-points.

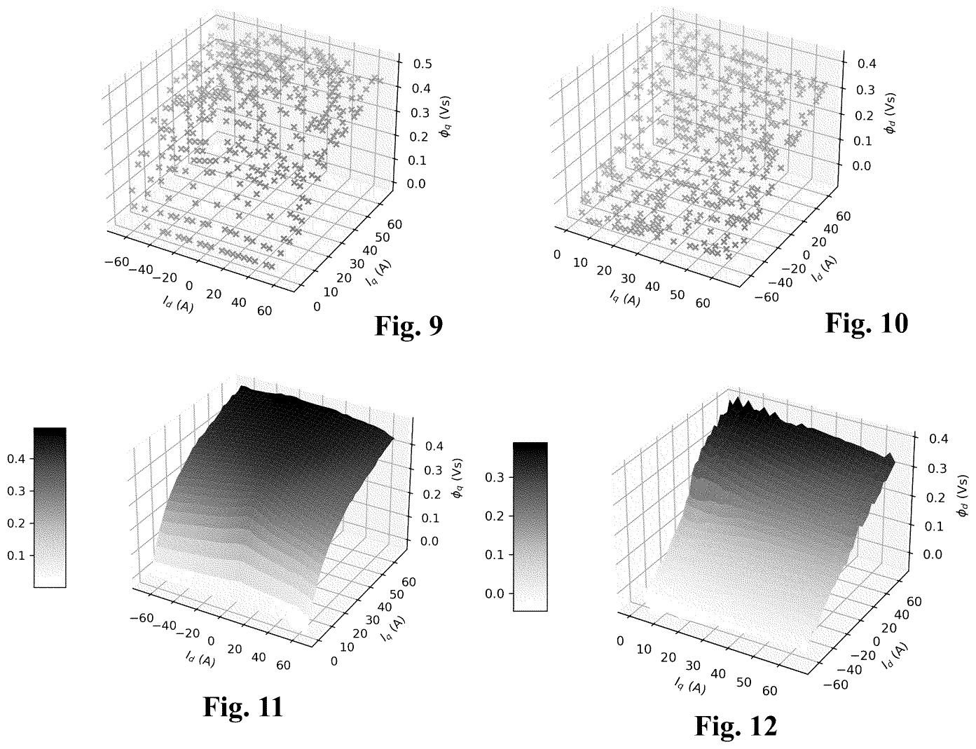

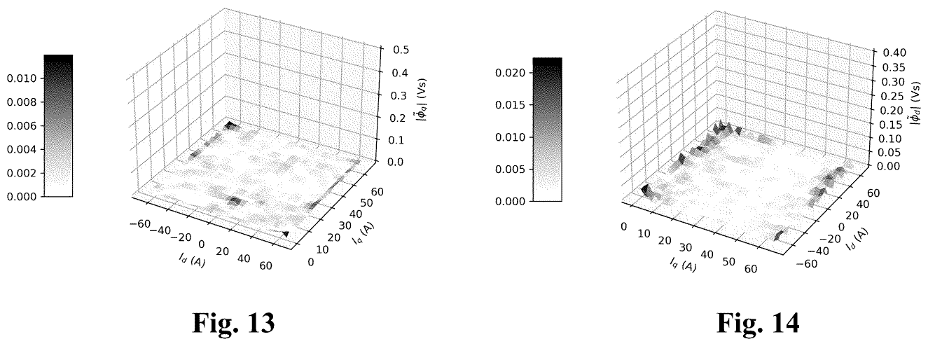

FIGS. 9 and 10 depict the random samples, across the (I_{d}, I_{q}) grid from true flux maps ϕ_{q} and ϕ_{d}, used to reconstruct the q and d axis flux maps \hat{ϕ}_{q} and \hat{ϕ}_{d}, respectively. FIGS. 11 and 12 show the corresponding reconstructed flux maps \hat{ϕ}_{q} and \hat{ϕ}_{d}, respectively. Comparing the true flux map ϕ_{q} in FIG. 4 with the reconstructed flux map \hat{ϕ}_{q} in FIG. 11 and the true flux map ϕ_{d} FIG. 6 with the reconstructed map \hat{ϕ}_{d} in FIG. 12, it can be concluded that the 2D flux maps for the THOR motor can be recovered reasonably well from 40% random samples. FIGS. 13 and 14 show the low reconstruction error between the true and reconstructed flux map in the q and d axis respectively. For representation purposes, a similar ϕ axis scale is used between FIG. 11 and FIG. 13, and between FIG. 12 and FIG. 14, respectively.

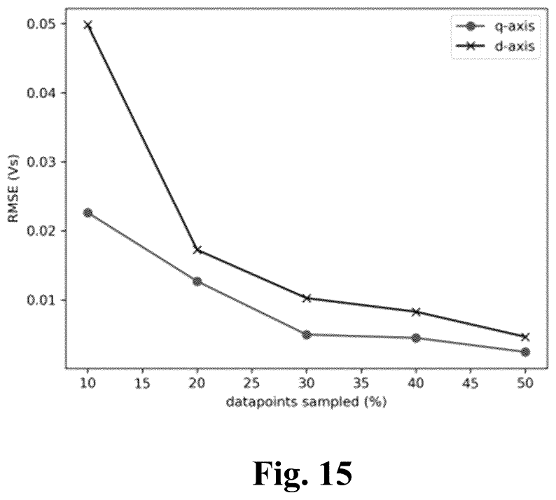

FIG. 15 shows the variation of the root mean squared error (RMSE) between the true and reconstructed flux map as function of the percentage of data-points used for reconstruction. It is evident that the reconstruction RMSE decreases with an increase in the percentage of data-points used for reconstruction. However, the marginal improvement in RMSE diminishes with an increase in the percentage of data-points used for reconstruction. This trend is expected as an increase in the number of known data-points implies less missing information and hence better identification. Since the flux maps are sparse in Fourier domain, once the dominant Fourier components have been identified, a further increase in the number of data-points provided would lead to identification of less significant Fourier components implying diminishing improvement in reconstruction error.

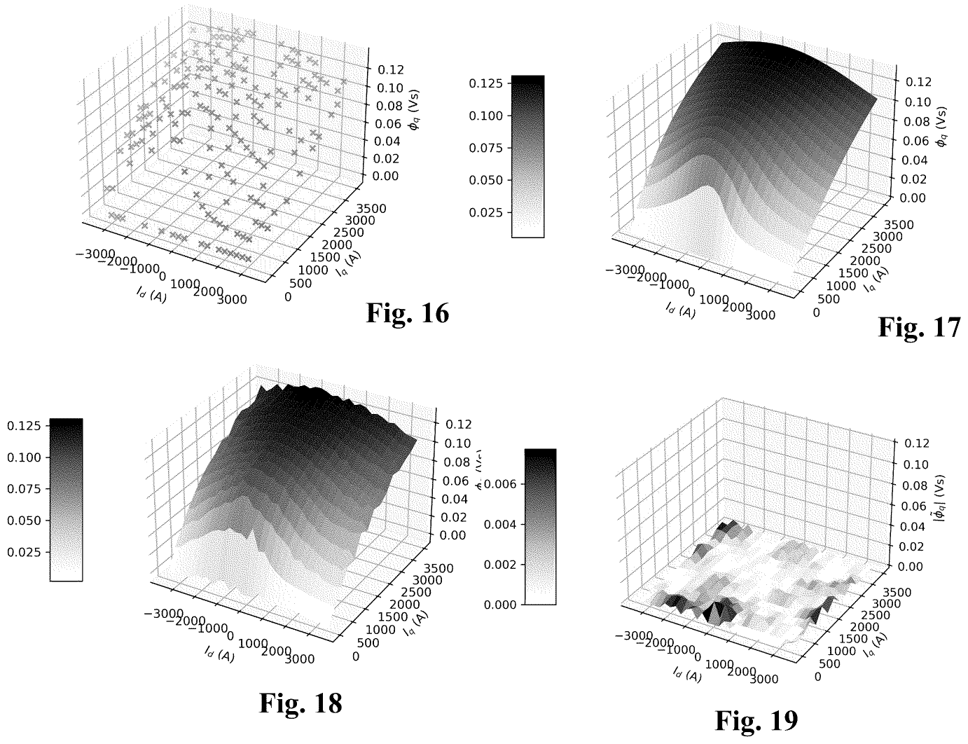

Finally, to demonstrate the generalizability of our method, we repeat the analysis to reconstruct the q axis flux map on a different motor dataset. We use the syreDefaultMotor dataset for this p. FIG. 16 shows the random samples used to reconstruct the q axis flux map for the syreDefaultMotor. Based on FIGS. 17, 18, and 19, it is evident that the proposed method generalizes well in reconstructing the flux maps.

### 3D Flux Map Reconstruction

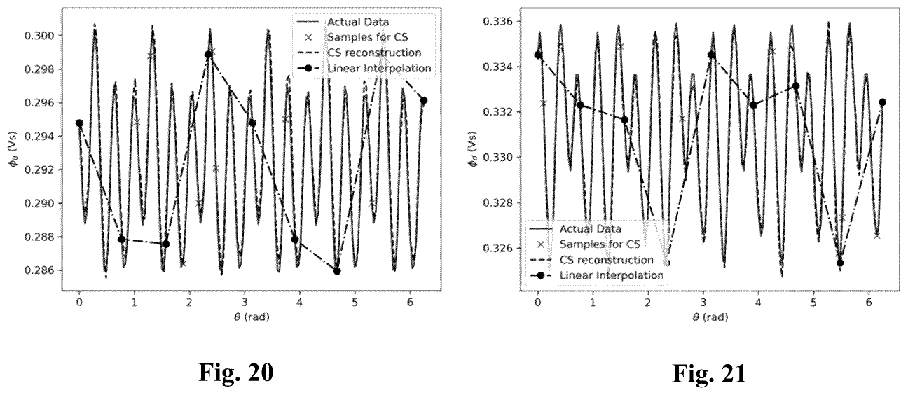

Having demonstrated the effectiveness of the proposed approach in reconstructing 2D flux maps, we apply it to reconstruct 3D flux maps and to acquire an analytical expression for 3D flux maps. The THOR data-set is once again used as simulation data. At every (I_{d}, I_{q}) grid point, we use just 9 random samples over [0,2π]. The algorithm proposed in 2.4 is then applied to reconstruct the 3D flux map. FIG. 20 illustrates the true flux variation, the random samples used and the reconstructed flux map variation in a slice of an exemplar 3D flux map in the q axis with respect to θ at a fixed (I_{d}, I_{q}) grid point. To highlight the reconstruction using limited sampling, we also include linear interpolation of 9 equi-spaced samples. Similarly, FIG. 21 illustrates the aforementioned quantities for the d axis.

The RMSE between the true and compressed sensing reconstructed flux map is found to be 0.0011 and 0.0009 for q, d axis respectively. The RMSE between the true and linear interpolation flux map is found to be 0.0053 and 0.0043 for q, d axis respectively. Thus we can see that the CS reconstruction reduces the error by approximately 5 times in both q, d axis. From FIGS. 20, 21 and the low reconstruction RMSE, it can be concluded that the spatial harmonic behavior at different values of [I_{d}, I_{q}] can be modelled using few 3D Fourier coefficients. The compressed sensing based approach can be applied to reconstruct the 3D flux map using few random samples along θ at each grid-point (I_{d}, I_{q}). It is also evident from FIGS. 20 and 21 that linear interpolation with the same number of equispaced random samples does not capture the harmonic variation.

To acquire an analytical expression for the 3D flux map, we leverage the fact that the maps are sparse in the Fourier domain and simplify using the Fourier basis to represent the signal. For ease of representation and to enable further simplification, we utilize the unrolled representation of the inverse Fourier transform instead of the one given in (9). We demonstrate the procedure on the q axis flux map; a similar procedure can be adopted to acquire the analytical expression for the d axis flux map. Let Z be the matrix of Fourier coefficients for the q axis flux map. The analytical expression can be simply written using the inverse Discrete Fourier transform expression as

$${ϕ}_{q} ( {n}_{1} , {n}_{2} , {n}_{3} ) = {\sum }_{a = 0}^{{N}_{1} - 1} {\sum }_{b = 0}^{{N}_{2} - 1} {\sum }_{c = 0}^{{N}_{3} - 1} \frac{Z ( a , b , c )}{{N}_{1} {N}_{2} {N}_{3}} \cdot {e}^{\{ 2 π j [ \frac{a {n}_{1}}{{N}_{1}} + \frac{b {n}_{2}}{{N}_{2}} + \frac{c {n}_{3}}{{N}_{3}} ] \}} , \qquad ( 11 )$$

where N₁, N₂, and N₃ correspond to the size of (I_{d}, I_{q}, θ) grid and n₁, n₂, n₃ correspond to the indices for the flux map under consideration. Note that n₁, n₂, n₃ are all integer numbers, corresponding to discrete current and angle. In case of motor control, the d, q axis currents and the angle are real numbers to control the motor based on a control accuracy parameter (predetermined control resolution). In some cases, the one or more processors 161 generate motor control commands and transmit the control commands to a motor controller 170 connected to the electric motor 130. The motor control commands are generated by using the reconstructed magnetic flux map model 165, and the motor controller 170 is configured to control the q-axis currents and d-axis currents of stator currents of the electric motor 130 based on the motor control commands. In this situation, we simply replace the integer indices (n₁, n₂, n₃) by real numbers (ñ₁, ñ₂, ñ₃) corresponding to the real measurements. For real parameters (I_{d}, I_{q}, θ) with I_{d}∈

$$[ - {I}_{dmax} , {I}_{dmax} ] , {I}_{q} ∈ [ 0 , {I}_{q max} ] , θ ∈ [ 0 , {θ}_{max} ] , {ñ}_{1} , {ñ}_{2} , {ñ}_{3} \text{can be calculated as} \{ \begin{matrix}{ñ}_{1} & = \frac{( {I}_{d} + {I}_{d max} ) ( {N}_{1} - 1 )}{2 {I}_{d max}} , \\ {ñ}_{2} & = \frac{{I}_{q} ( {N}_{2} - 1 )}{{I}_{q max}} , \\ {ñ}_{3} & = \frac{θ ( {N}_{3} - 1 )}{{θ}_{max}} .\end{matrix} \qquad ( 12 )$$

Note that Z is a sparse matrix, meaning that most entries of Z are zero. Leveraging this sparsity of Z and combining (11) and (12), we can write the analytical magnetic flux model as

$${\tilde{ϕ}}_{q} ( {I}_{d} , {I}_{q} , θ ) = {\sum }_{Z ( a , b , c ) \neq 0} \frac{Z ( a , b , c )}{{N}_{1} {N}_{2} {N}_{3}} \cdot {e}^{\{ 2 π j [ \frac{a ( {I}_{d} + {I}_{dmax} )}{2 {I}_{dmax}} \cdot \frac{{N}_{1} - 1}{{N}_{1}} + \frac{b {I}_{q}}{{I}_{q max}} \cdot \frac{{N}_{2} - 1}{{N}_{2}} + \frac{c θ}{{θ}_{max}} \cdot \frac{{N}_{3} - 1}{{N}_{3}} ] \}} . \qquad ( 13 )$$

Thus (13) provides a compact analytical function for flux maps accounting for spatial harmonics.

According to some embodiments of the present invention, a novel compressed sensing based approach is provided to reconstruct 2D and 3D flux maps. With limited random samples, it was shown through simulation studies that the entire flux map could be reconstructed. In particular, with just 40% of data-points, the entire 2D flux map was reconstructed with reasonable accuracy. Thus such an approach would reduce the number of grid-points that need to be tested while conducting experimental flux map identification.

Also, individual embodiments may be described as a process which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process may be terminated when its operations are completed, but may have additional steps not discussed or included in a figure. Furthermore, not all operations in any particularly described process may occur in all embodiments. A process may correspond to a method, a function, a procedure, a subroutine, a subprogram, etc. When a process corresponds to a function, the function's termination can correspond to a return of the function to the calling function or the main function.

Furthermore, embodiments of the subject matter disclosed may be implemented, at least in part, either manually or automatically. Manual or automatic implementations may be executed, or at least assisted, through the use of machines, hardware, software, firmware, middleware, microcode, hardware description languages, or any combination thereof. When implemented in software, firmware, middleware or microcode, the program code or code segments to perform the necessary tasks may be stored in a machine-readable medium. A processor(s) may perform the necessary tasks.

The above-described embodiments of the present invention can be implemented in any of numerous ways. For example, the embodiments may be implemented using hardware, software or a combination thereof. When implemented in software, the software code can be executed on any suitable processor or collection of processors, whether provided in a single computer or distributed among multiple computers. Such processors may be implemented as integrated circuits, with one or more processors in an integrated circuit component. Though, a processor may be implemented using circuitry in any suitable format.

Also, the embodiments of the invention may be embodied as a method, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Use of ordinal terms such as “first,” “second,” in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Although the invention has been described by way of examples of preferred embodiments, it is to be understood that various other adaptations and modifications can be made within the spirit and scope of the invention.

Therefore, it is the object of the appended claims to cover all such variations and modifications as come within the true spirit and scope of the invention.

We claim:

1. A non-transitory computer-readable medium having stored thereon a set of instructions for reconstructing a magnetic flux map from measurements of a magnetic flux of an electric motor, which when performed by one or more processors, cause the one or more processors to at least performs steps of: generating an intermediate reconstructed flux map dataset by performing a zero-padding method for the measurements of the magnetic flux;
and iteratively
generating a discrete Fourier Transform (DFT) dataset by performing a Fast Fourier Transformation (FFT) for the intermediate reconstructed flux map dataset; generating a soft-thresholded dataset by performing a soft-thresholding process for the DFT dataset based on a regularizing threshold;
reconstructing a new intermediate magnetic flux map from an inverse-FFT dataset by performing an inverse-FFT process for the soft-thresholded dataset;
performing a data-consistency enforcement process for the reconstructed magnetic flux map to update the reconstructed new magnetic flux map by using measured flux map points to replace with the corresponding reconstructed flux map points, until a convergence condition defined by a convergence parameter is met;
storing the updated reconstructed new magnetic flux map into a memory, wherein each entry of the updated reconstructed new magnetic flux map is represented by q-axis fluxes and d-axis fluxes, as a function of q-axis currents, d-axis currents, and rotor electrical angle position.

2. The non-transitory computer-readable medium of claim 1, wherein the measurements of the magnetic flux are 2-dimensional (2D) measurement data or 3-dimensional (3D) measurement data.

3. The non-transitory computer-readable medium of claim 1, wherein the one or more processors generate motor control commands and transmit the control commands to a motor controller connected to the electric motor, wherein the motor control commands are generated by using the stored reconstructed magnetic flux map, wherein the motor controller is configured to control the q-axis currents and d-axis currents of stator currents of the electric motor based on the motor control commands provided by an operator.

4. The non-transitory computer-readable medium of claim 2, wherein the one or more processors receive operation signals of the electric motor from sensors arranged on the electric motor and receive a setting signal from the motor controller, wherein the one or more processers generate motor control commands in response to the operation signals and the setting signal and transmit the motor control commands to the motor controller.

5. The non-transitory computer-readable medium of claim 1, further comprises mapping the updated reconstructed new magnetic flux map on a grid determined based on a control accuracy parameter, wherein the control accuracy parameter is calculated based on a predetermined control resolution of the electric motor.

6. The non-transitory computer-readable medium of claim 1, wherein the electric motor is a permanent magnet machine.

7. The non-transitory computer-readable medium of claim 1, wherein the one or more processors receive the measurements of the magnetic flux via a data interface connected to the one or more processors from a data server storing a magnetic flux measurement dataset via a network.

8. The non-transitory computer-readable medium of claim 1, wherein the zero-padding method is performed for missing points of the measurements of the magnetic flux.

9. The non-transitory computer-readable medium of claim 1, wherein the measurements of the magnetic flux are torque measurement datasets of the electric motor.

10. A magnetic flux mapping system for reconstructing a magnetic flux map from measurements of a magnetic flux of an electric motor comprising:
an interface circuit connected to a database storage and configured to receive the measurements of the magnetic flux of the electric motor from a data storage via a network;
one or more processors;
a memory having stored thereon a set of instructions for reconstructing the magnetic flux map, which when performed by the one or more processors, cause the one or more processors to at least performs steps of:
generating an intermediate reconstructed flux map dataset by performing a zero-padding method for the measurements of the magnetic flux;
and iteratively
generating a discrete Fourier Transform (DFT) dataset by performing a Fast Fourier Transformation (FFT) for the intermediate reconstructed flux map dataset; generating a soft-thresholded dataset by performing a soft-thresholding process for the DFT dataset based on a regularizing threshold;
reconstructing a new intermediate magnetic flux map from an inverse-FFT dataset by performing an inverse-FFT process for the soft-thresholded dataset;
performing a data-consistency enforcement process for the reconstructed magnetic flux map to update the reconstructed new magnetic flux map by using measured flux map points to replace with the corresponding reconstructed flux map points, until a convergence condition defined by a convergence parameter is met;
storing the updated reconstructed new magnetic flux map into a memory, wherein each entry of the updated reconstructed new magnetic flux map is represented by q-axis fluxes and d-axis fluxes, as a function of q-axis currents, d-axis currents, and rotor electrical angle position.

11. The system of claim 10, wherein the measurements of the magnetic flux are 2-dimensional (2D) measurement data or 3-dimensional (3D) measurement data.

12. The system of claim 10, wherein the one or more processors generate motor control commands and transmit the control commands to a motor controller connected to the electric motor, wherein the motor control commands are generated by using the stored reconstructed magnetic flux map, wherein the motor controller is configured to control the q-axis currents and d-axis currents of stator currents of the electric motor based on the motor control commands provided by an operator.

13. The system of claim 11 wherein the one or more processors receive operation signals of the electric motor from sensors arranged on the electric motor and receive a setting signal from the motor controller, wherein the one or more processers generate motor control commands in response to the operation signals and the setting signal and transmit the motor control commands to the motor controller.

14. The system of claim 10, further comprises mapping the updated reconstructed new magnetic flux map on a grid determined based on a control accuracy parameter, wherein the control accuracy parameter is calculated based on a predetermined control resolution of the electric motor.

15. The system of claim 10, wherein the electric motor is a permanent magnet machine.

16. The system of claim 10, wherein the one or more processors receive the measurements of the magnetic flux via a data interface connected to the one or more processors from a data server storing a magnetic flux measurement dataset via a network.

17. The system of claim 10, wherein the zero-padding method is performed for missing points of the measurements of the magnetic flux.

18. The system of claim 10, wherein the measurements of the magnetic flux are torque measurement datasets of the electric motor.
